(19) United States
(12) Patent Application Publication
(10) Pub. No.: US 2023/0385507 A1
(43) Pub. Date: Nov. 30, 2023

(54) AI-BASED COMPONENT PLACEMENT TECHNOLOGY FOR PCB CIRCUITS

(71) Applicant: Intel Corporation, Santa Clara, CA (US)

(72) Inventors: Jianfang Zhu, Portland, OR (US); Adam Norman, Forest Grove, OR (US); Min Suet Lim, Penang (MY); Miaomiao Ma, Sunnyvale, CA (US); Mackenzie Norman, Portland, OR (US); John Vu, Rancho Cordova, CA (US); Ching Leong Ooi, Penang (MY); Eng Same Tan, Pinang (MY); Luis Carlos Alvarez Mata, Cartago (CR)

(21) Appl. No.: 18/326,772

(22) Filed: May 31, 2023

(51) Int. Cl. G06F 30/392; G06F 30/27

(52) U.S. Cl. CPC G06F 30/392; G06F 30/27

(57) ABSTRACT

Systems, apparatuses and methods may provide for technology that receives parameter results and scores of one or more local sessions with respect to subcircuit components in a bounded area, aggregates the parameter results and scores, and generates a global placement model based on an output of the aggregated parameter results and scores.

### TECHNICAL FIELD

Embodiments generally relate to the design of printed circuit board (PCB) layouts (e.g., “floorplans”). More particularly, embodiments relate to artificial intelligence (AI) based component placement technology for PCB circuits.

### BACKGROUND

PCB component placement typically involves the participation of highly skilled and experienced engineers, as it is becoming increasingly difficult and expensive to keep up with the demand as the number of central processing unit (CPU) stock keeping units (SKUs) and platforms grows. Although certain electronic design automation (EDA) tools may offer auto-placement routines, such tools are often not suitable for more complex circuit designs.

### BRIEF DESCRIPTION OF THE DRAWINGS

The various advantages of the embodiments will become apparent to one skilled in the art by reading the following specification and appended claims, and by referencing the following drawings, in which:

FIG. 1 is a plan view of an example of a sample subcircuit component placement;

FIG. 2 is a flow diagram of an example of an automated placement procedure and associated parameters according to an embodiment;

FIG. 3 is an illustration of an example of a plurality of local rating sessions according to an embodiment;

FIG. 4 is a comparative plot of an example of conventional placement results and enhanced placement results according to an embodiment;

FIG. 5A is a flowchart of an example of a method of conducting a plurality of local rating sessions according to an embodiment;

FIG. 5B is a flowchart of an example of a method of operating a performance-enhanced computing system according to an embodiment;

FIG. 6 is a plot of an example of score collection results between random users for identical placements according to an embodiment;

FIG. 7 is a set of comparative charts of an example of conventional performance results and enhanced performance results according to an embodiment;

FIG. 8 is an average improvement chart for an example placement solution according to an embodiment;

FIG. 9 is a comparative plan view of an example of a conventional subcircuit placement and an enhanced subcircuit placement according to an embodiment;

FIG. 10 is a block diagram of an example of a performance-enhanced computing system according to an embodiment;

FIG. 11 is an illustration of an example of a semiconductor package apparatus according to an embodiment;

FIG. 12 is a block diagram of an example of a processor according to an embodiment; and

FIG. 13 is a block diagram of an example of a multi-processor based computing system according to an embodiment.

### DETAILED DESCRIPTION

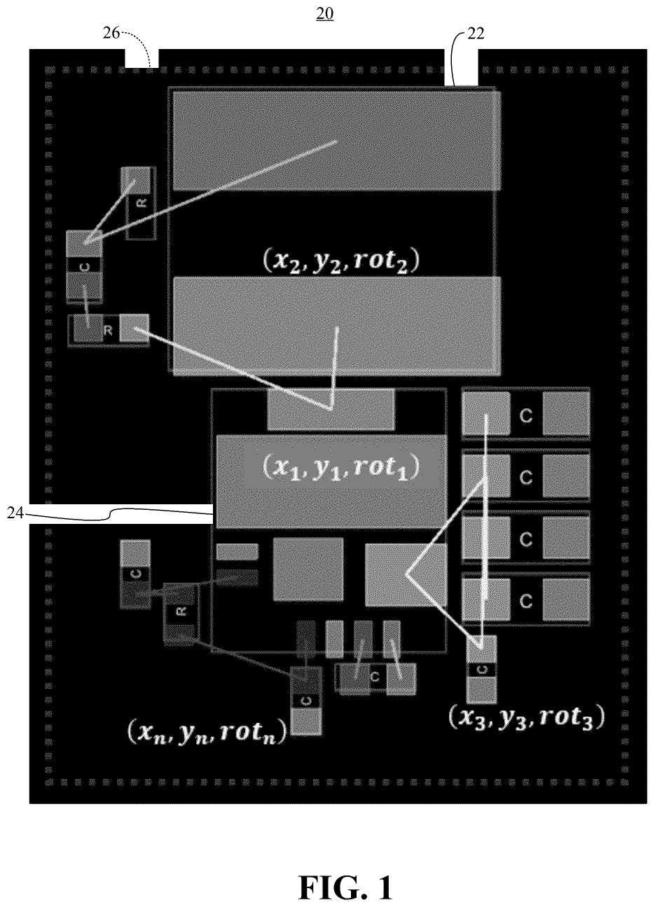

Turning now to FIG. 1, a subcircuit placement 20 is shown in which N components in a subcircuit include an inductor 22, an integrated circuit 24, and various resistors (R) and capacitors (C) that are to be placed within a bounded area 26 (e.g., “room outline”). Each component has an x,y location as well as a rotation (e.g., “rot”) attribute.

There are various design rules to be met as well as various design criteria that can be optimized. A partial list of the design rules and objectives are provided in Table I below.

Table I

| | | | Algorithmic |
|---|---|---|---|
| Name | Type | Description | Complexity |
| Overlap | Rule | Components do not overlap other components | Low |
| Spacing | Rule | Space between components and pins obeys guidelines | High |
| Height | Rule | Components do not exceed height in certain locations | Low |
| Route | Objective | Net length between connected components (typically | High |
| Length | | minimized) | |
| Area | Objective | Footprint of component placement (typically | T Low |
| | | minimized) | |
| Plane | Objective | Power and ground planes are impacted by component | High |
| integrity | | placement | |
| Aesthetics | Objective | Various preferences (alignment, duplication, | High |
| | | orientation) | |

The technology described herein includes an augmented intelligence approach that alleviates difficulties encountered in subcircuit placement. The technology reduces the workload for engineers and accelerates the learning curve for junior engineers. More particularly, embodiments are able to capture design constraints defined from multiple interactions and capture design user preferences.

The technology described herein uses a set of parameterized placement procedures that adhere to the design rules and constraints of the circuit. Additionally, a scoring of the placements has also been parameterized. For example, minimize (a*overlap-area+b*net-length+c*area) may be used, where a, b, c are optimization parameters.

This approach enables trade-offs to be made among user preferences such as component overlap, area, net-length and so forth. The parameterization of the procedures avoids the difficulties of direct placement (xᵢ, yᵢ, rotᵢ) optimization and permits the use of federated learning (e.g., only parameters are saved, not the actual placements). Federated learning enables embodiments to 1) build personal models for capturing the preferences of individual designers, 2) build a global model to improve overall placement quality of the artificial intelligence (AI) tool, and 3) protect data privacy.

Indeed, the design files for different entities (e.g., customers) may not be able to be shared. Using federated learning can keep the files local to protect data confidentiality and avoid compliance issues. Applying federated learning to circuit placement usage as described herein uses the rating of different placement options by one user to train a personal model of placement parameters (e.g., enabled by parameterized placement). Using this method, the experience and personal preferences of a designer can be effectively captured. By aggregating the ratings of all users, a global model of placement parameters can be built as the default model for any user (e.g., capturing the experience and considerations of multiple design factors from all of the designers participating in the local rating sessions).

The result is faster placements than manual placement (e.g., ˜3.5 hours to place components on a PCB using the technology described herein compared to days under design engineer manual placement). Embodiments also facilitate junior engineer training, provide superior performance over existing auto-placement routines, enable trainability through machine learning, and are suitable to federated learning). As already noted, the AI-based technology described herein can reduce the PCB component placement time from days (e.g., manual efforts) to hours. Compared to manually placing components one by one, embodiments can place tens of subcircuits (e.g., each containing tens of components) simultaneously and in parallel within hours. The technology described herein generates and recommends a few top scored placement options for users to choose from. The combined leanings from expert rules and active labeling of placement options by experts produces superior placement quality (e.g., close to human expert placement) compared to existing auto-placement solutions.

The problem of subcircuit placement can be viewed as a multi-objective optimization problem:
Maximize placement desirability {(xᵢ, yᵢ, rotᵢ)} for i=1:n, where placement desirability can be a user defined or learned function of placement scores and features.
Instead of directly optimizing for (xᵢ, yᵢ, rotᵢ), the technology described herein includes parameterized placement procedures (parameters aᵢ), where the parameters can be optimized. This optimization provides a significant computational advantage. In one example, direct optimization is used only under restricted circumstances.

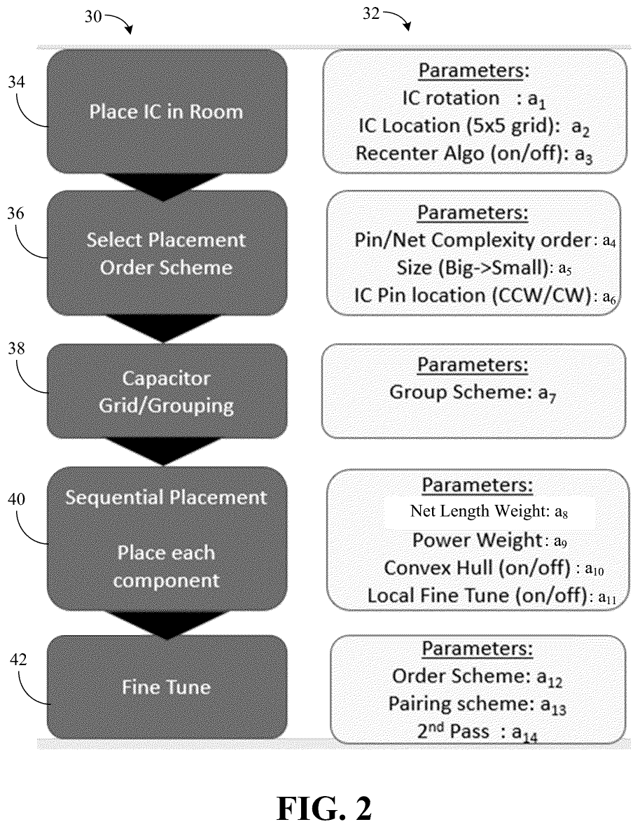

Turning now to FIG. 2, an example of a placement flow 30 and associated parameters 32 is shown. In the illustrated example, processing block 34 uses a circuit rotation parameter (e.g., a₁), a circuit location parameter (e.g., a₂), and a recenter procedure parameter (e.g., a₃) to initially place the integrate circuit (IC) in the room. Processing block 36 uses a complexity order parameter (e.g., a₄), a size parameter (e.g., a₅), and a pin location parameter (e.g., a₆) to select a placement order scheme. Additionally, processing block 38 may use a group scheme parameter (e.g., a₇) to conduct a capacitor grid/grouping. In an embodiment, processing block 40 uses a route length weight parameter (e.g., a₈), a power weight parameter (e.g., a₉), a convex hull parameter (e.g., a₁₀), and a local fine tune parameter (e.g., a₁₁) to sequentially place each component. In addition, processing block 42 may use an order scheme parameter (e.g., a₁₂), a pairing scheme parameter (e.g., a₁₃), and a second pass parameter (e.g., a₁₄) to fine tune the placement.

There are numerous placement procedures (not shown), so choosing a placement procedure is also a parameter. Thus, the number of parameters for the placement procedures is not limited to fourteen (e.g., new parameters may be added as design complexities grow or with different sets of circuitries). Where some of the parameters can take on more than two values, the number of permutations is relatively high. Since each combination of parameters can generate a new placement, the number of possible placements from parameters is also substantially high. Machine learning technology is used to accelerate the discovery of the best set of parameters.

The various scoring procedures (e.g., netlength, area, alignment, uniformity, . . . ) can also be parameterized. It is this combined parameter space (placement+scoring) that lends itself to machine learning and federated learning and provides a highly evolvable scheme for future placement enhancements. Additionally, the federated learning feedback can provide valuable insight to junior engineers through the use of variable importance techniques. Moreover, the use of federated learning can provide a mechanism to create a stop/exit criteria for the machine learning and optimization schemes.

### Learning/Training Schemes

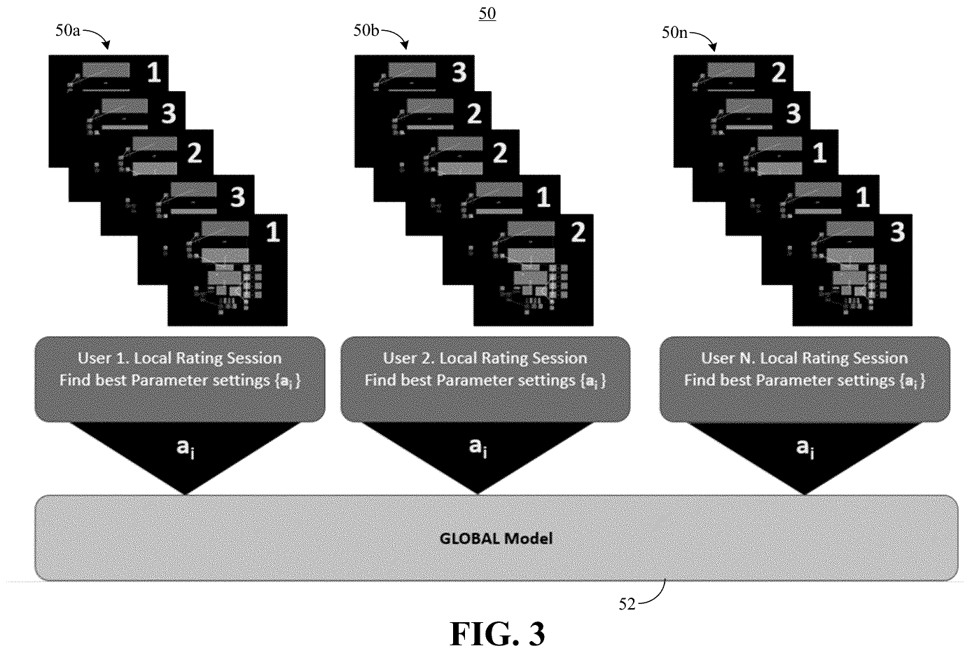

FIG. 3 shows a plurality of local rating sessions 50 (50a-50n) that are conducted for a plurality of (e.g., N) users. Alternatively, the local rating sessions 50 may be conducted for a plurality of entities (e.g., with each entity including one or more users). Each local rating session 50 has full access to all placement information and the user can repetitively rate placements to train the learning procedure. Thus, a first local rating session 50a is conducted for a first user (“User 1”) and includes parameterized placements of the subcircuit components in the bounded area, score collections (five score collections in the illustrated example) for the parameterized placements, and a training of a local machine learning model based on the parameterized placements and the score collections. Similarly, a second local rating session 50b is conducted for a second user (“User 2”) and includes parameterized placements of the subcircuit components in the bounded area, score collections (five score collections in the illustrated example) for the parameterized placements, and a training of a local machine learning model based on the parameterized placements and the score collections. In the illustrated example, the placements are rated “1” (e.g., red), “2” (e.g., yellow), or “3” (e.g., green) for coarse scoring by local users. A global model 52, however, is federated and therefore no direct placement/customer information is shared (e.g., only the anonymous parameters as well as potentially some meta data).

### Local Learning Scheme

A single user (or entity) can rate the various options provided by the placement procedures (e.g., many placements are possible). As the user provides the feedback, a machine learning model (e.g., decision tree) can be built to:
Learn the preferred parameters for the user for each design class compared to heuristic-based universe parameter choice; and
Build a model to score the placement more in line with user preferences compared to the heuristic-based scoring, ignoring user preference/differences.

Both of these operations improve the performance of the placement and reduce the time taken to find optimal placements. Since the rating session 50 is local, the placement information can be used in conjunction with the learnings.

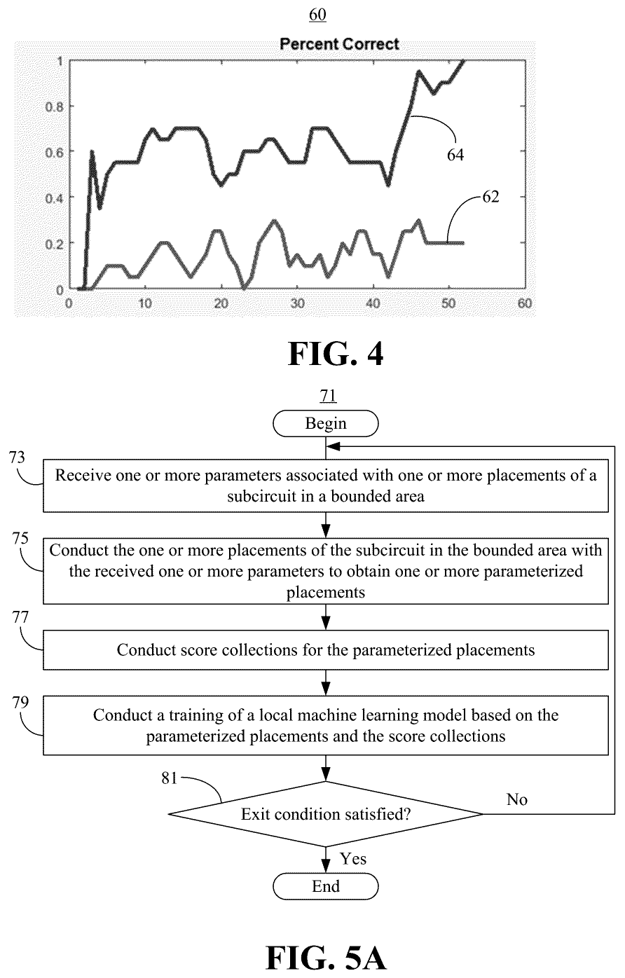

FIG. 4 shows placement results plot 60 of a heuristic curve 62 (e.g., using only netlength) compared to a learned curve 64. As can be seen, the learned model is able to better predict the user ratings than the heuristic.

### Global Learning Scheme (Federated Learning)

A federated learning approach can be applied to aggregate the “results” (e.g., the user-ranked scores) from local learning sessions. Since the results from local learning are purely parameters (e.g., design information and/or layout information is excluded), those results can used to build a global parameter/scoring model that can be distributed back to the entire user base.

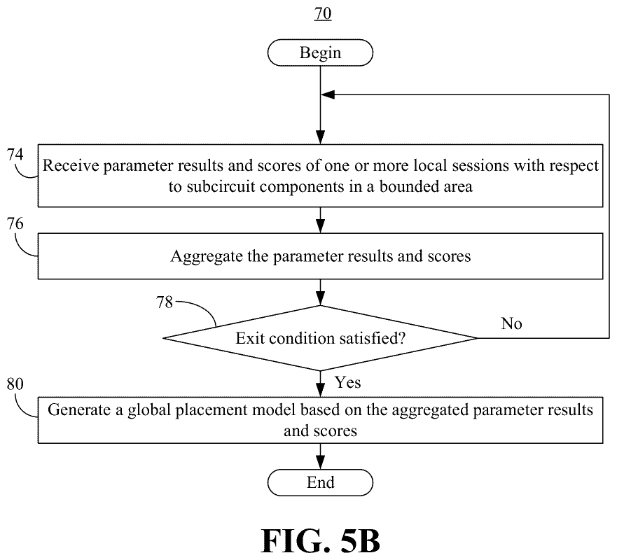

FIG. 5A shows a method 71 of conducting a plurality of local rating sessions with respect to subcircuit components in a bounded area. The method 71 may generally be conducted with respect to a plurality of users and/or a plurality of entities. More particularly, the method 71 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Computer program code to carry out operations shown in the method 71 can be written in any combination of one or more programming languages, including an object-oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 73 receives one or more parameters associated with one or more placements of a subcircuit in a bounded area. Block 75 conducts the one or more placements of the subcircuit in the bounded area with the received one or more parameters to obtain one or more parameterized placements. Block 77 conducts score collections for the parameterized placements. In one example, the score collections are parameterized score collections. Additionally, block 79 conducts a training of a local machine learning model based on the parameterized placements and the score collections. A determination is made at block 81 as to whether an exit condition is satisfied. In one example, block 81 includes determining whether a confidence level of the output of the local machine learning model has reached a confidence threshold and/or whether an error level of the output of the local machine learning model has fallen below an error threshold. If the exit condition has not been satisfied, the method 71 returns to block 73 (e.g., for a new user/entity). Otherwise, the method 71 terminates.

FIG. 5B shows a method 70 of operating a performance-enhanced computing system. The method 70 may be implemented in one or more modules as a set of logic instructions stored in a machine- or computer-readable storage medium such as RAM) ROM, PROM, firmware, flash memory, etc., in hardware, or any combination thereof.

Illustrated processing block 74 receives parameter results and scores of one or more local sessions with respect to subcircuit components in a bounded area and block 76 aggregates the parameter results and scores. In one example, block 76 excludes design data and/or layout data from the aggregated parameter results. The aggregated parameter results may include, for example, a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter, etc., or any combination thereof.

The circuit rotation parameter refers to the rotation angle of a component, chosen from 0°, 90°, 180° and 270°. The recenter procedure parameter determines whether to place the circuit components at the center of the bounding box. The complexity order parameter determines the placement order of the components (e.g., which component is placed first). The size parameter refers to the component size. The pin location parameter refers to the pin location in each component. Therefore, the size parameter and pin parameter affect the complexity order parameter. The group scheme parameter determines whether certain components are grouped together to obtain better placement results. The route length weight parameter is the weight of netlength in the optimization objective. The power weight parameter refers to the power net lengths. The convex hull parameter is the convex hull bounding box of all the components. The local fine tune parameter fine tunes the locations of each component to obtain better placement results. The order scheme parameter and pairing scheme parameter are from machine learning of user preferences to generate results that better suit to the user. The second pass parameter determines whether a second run is appropriate based the placement quality.

Block 78 determines whether an exit (e.g., stop) condition has been satisfied. In one example, block 78 includes determining whether a confidence level of the aggregated parameter results and scores has reached a confidence threshold and/or whether an error level of the output of the aggregated parameter results and scores has fallen below an error threshold. If the exit condition has not been satisfied, the method 70 returns to block 74 (e.g., for a new user/entity). Otherwise, block 80 generates a global placement model based on the aggregated parameter results and scores.

The methods 70 and/or 71 (FIG. 5A) therefore enhance performance at least to the extent that generating the global placement model based on the aggregated parameter results and scores is faster than manual placement. Additionally, training the local machine learning model based on the parameterized placements provides more accurate results and facilitates the training of junior engineers/personnel. Moreover, excluding the design and/or layout data from the aggregated parameter results addresses privacy concerns while maintaining a relatively high level of accuracy.

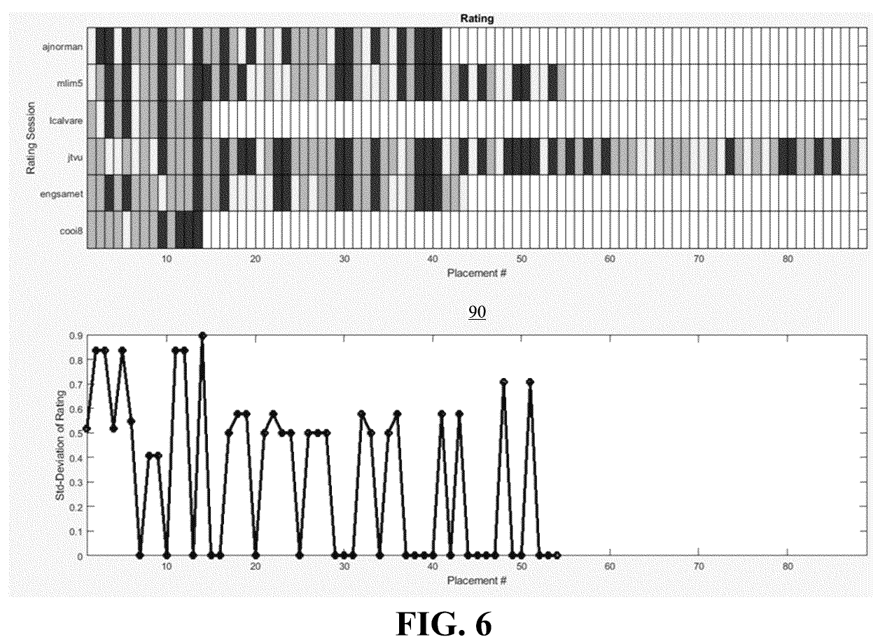

FIG. 6 shows a plot 90 of the variation in ratings between six different users. The plot 90 therefore demonstrates the technical advantageousness of “learned” scoring as there can be significant differences in personal opinions.

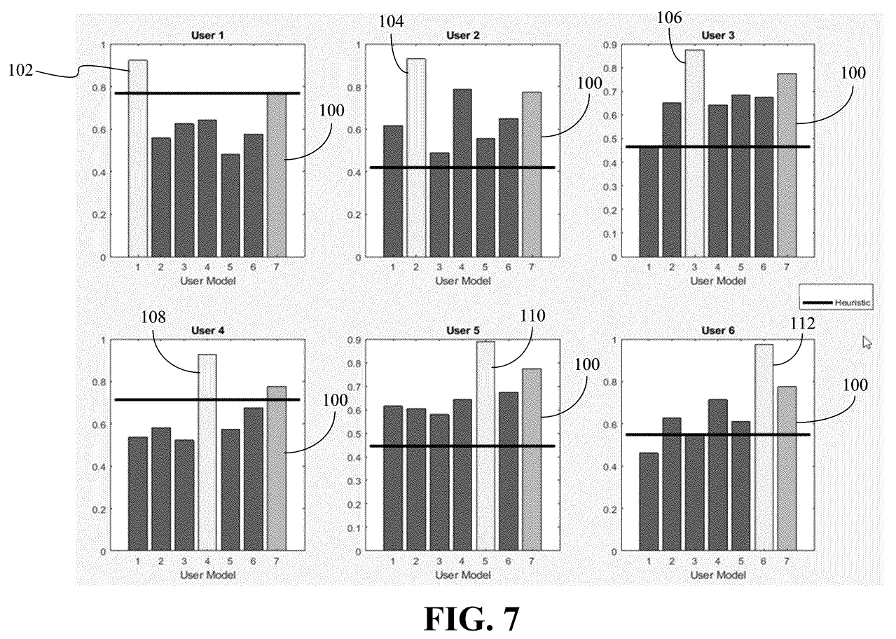

Turning now to FIG. 7, a global model 100 is created from the aggregation of six users and compared to all individual models. As expected, a personalized individual model 102 for a first user, a personalized individual model 104 for a second user, a personalized individual model 106 for a third user, a personalized individual model 108 for a fourth user, a personalized individual model 110 for a fifth user, and a personalized individual model 112 for a sixth user outperform the global model 100. The global model 100 still outperforms, however, the heuristic scoring (horizontal line) across all users, whereas applying the model of another user (remaining bars) to a new user is typically worse performing than the global model 100.

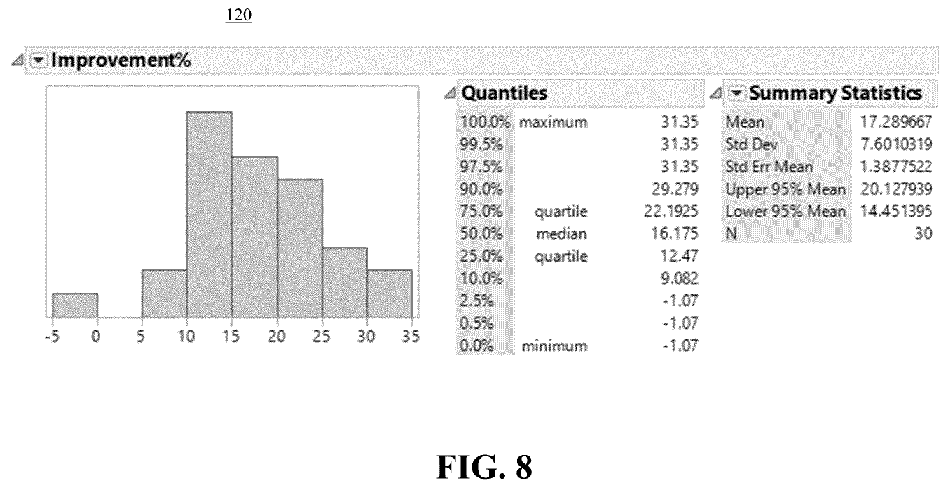

FIG. 8 summarizes the benefits of the technology described herein in a percent improvement chart 120. In the illustrated example, an average improvement of 17% is observed in prediction by using the global model over other individual models.

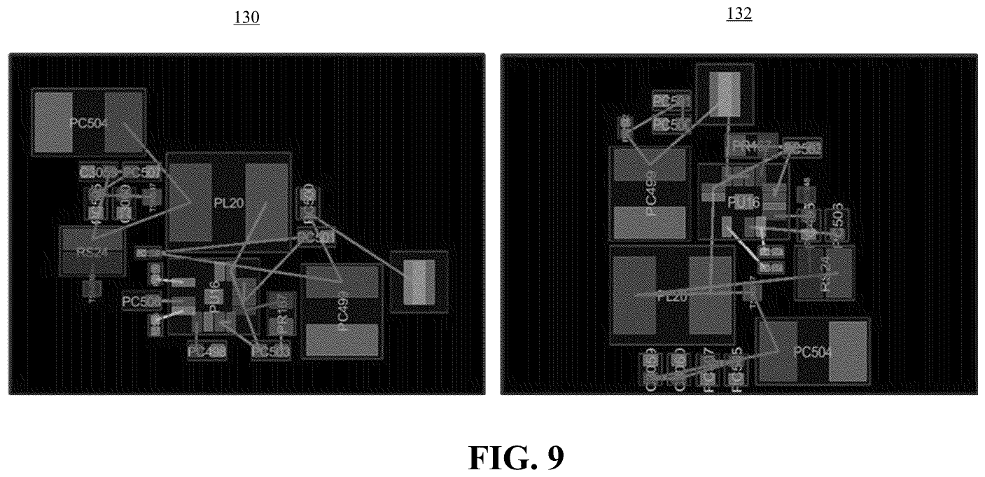

FIG. 9 shows a comparison between a conventional placement 130 and an enhanced placement 132 based on the federated learning technology described herein. Because the illustrated conventional placement 130 uses direct optimization of (xᵢ, yᵢ, rotᵢ) only, the conventional placement 130 is unable to capture the user preference in obtaining an aesthetic uniform design. By contrast, the enhanced placement 132 (e.g., after a global learning trained model is applied), takes into consideration the uniformity of the placement to obtain the smallest area.

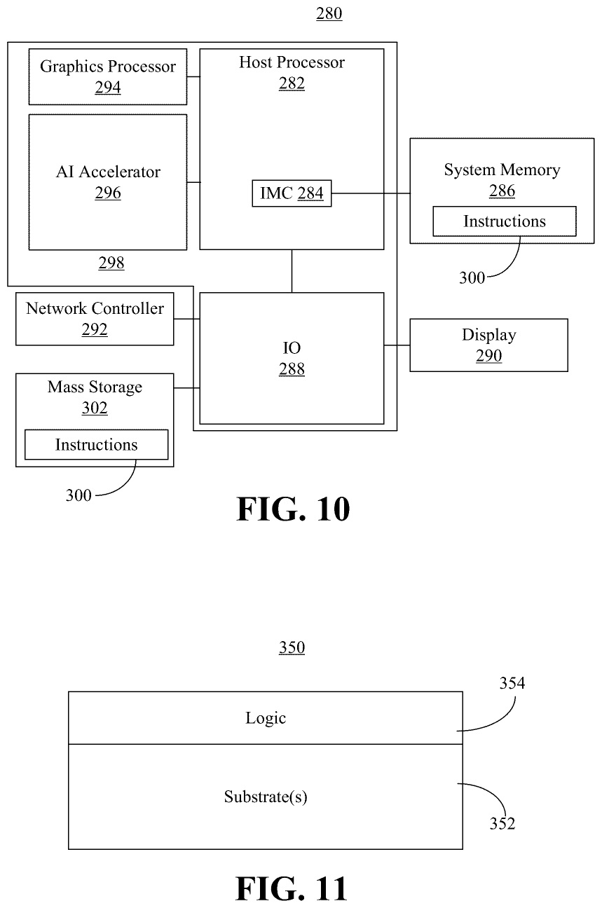

Turning now to FIG. 10, a performance-enhanced computing system 280 is shown. The system 280 may generally be part of an electronic device/platform having computing functionality (e.g., personal digital assistant/PDA, notebook computer, tablet computer, convertible tablet, edge node, server, cloud computing infrastructure), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM including a plurality of dynamic RAMs/DRAMs). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 (e.g., specialized processor) into a system on chip (SoC) 298.

In an embodiment, the AI accelerator 296 and/or the host processor 282 execute instructions 300 retrieved from the system memory 286 and/or the mass storage 302 to perform one or more aspects of the placement flow 30, the method 71 (FIG. 5A) and/or the method 70 (FIG. 5B), already discussed. Thus, execution of the instructions 300 causes the AI accelerator 296, the host processor 282 and/or the computing system 280 to conduct a plurality of local rating sessions with respect to subcircuit components in a bounded area, wherein each local rating session includes parameterized placements of the subcircuit components in the bounded area, score collections for the parameterized placements, and a training of a local machine learning model based on the parameterized placements and the score collections. Execution of the instructions 300 may also cause the AI accelerator 296, the host processor 282 and/or the computing system to receive parameter results and scores of one or more local sessions with respect to subcircuit components in a bounded area, aggregate the parameter results and scores, and generate a global placement model based on the aggregated parameter results and scores.

The computing system 280 is therefore considered performance-enhanced at least to the extent that generating the global placement model based on the aggregated parameter results and scores is faster than manual placement. Additionally, training the local machine learning model based on the parameterized placements provides more accurate results and facilitates the training of junior engineers/personnel. Moreover, excluding the design and/or layout data from the aggregated parameter results addresses privacy concerns while maintaining a relatively high level of accuracy.

FIG. 11 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of the placement flow 30, the method 71 (FIG. 5A) and/or the method 70 (FIG. 5B), already discussed.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

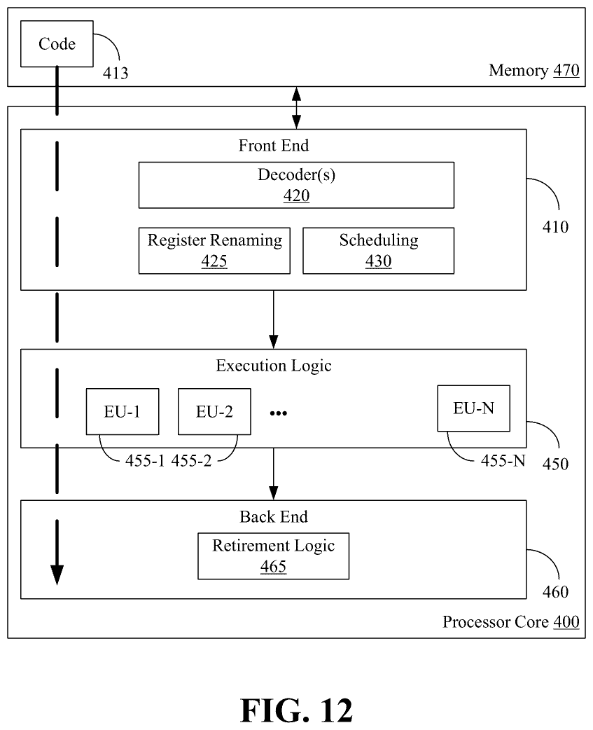

FIG. 12 illustrates a processor core 400 according to one embodiment. The processor core 400 may be the core for any type of processor, such as a micro-processor, an embedded processor, a digital signal processor (DSP), a network processor, or other device to execute code. Although only one processor core 400 is illustrated in FIG. 12, a processing element may alternatively include more than one of the processor core 400 illustrated in FIG. 12. The processor core 400 may be a single-threaded core or, for at least one embodiment, the processor core 400 may be multithreaded in that it may include more than one hardware thread context (or “logical processor”) per core.

FIG. 12 also illustrates a memory 470 coupled to the processor core 400. The memory 470 may be any of a wide variety of memories (including various layers of memory hierarchy) as are known or otherwise available to those of skill in the art. The memory 470 may include one or more code 413 instruction(s) to be executed by the processor core 400, wherein the code 413 may implement the placement flow 30, the method 71 (FIG. 5A) and/or the method 70 (FIG. 5B), already discussed. The processor core 400 follows a program sequence of instructions indicated by the code 413. Each instruction may enter a front end portion 410 and be processed by one or more decoders 420. The decoder 420 may generate as its output a micro operation such as a fixed width micro operation in a predefined format, or may generate other instructions, microinstructions, or control signals which reflect the original code instruction. The illustrated front end portion 410 also includes register renaming logic 425 and scheduling logic 430, which generally allocate resources and queue the operation corresponding to the convert instruction for execution.

The processor core 400 is shown including execution logic 450 having a set of execution units 455-1 through 455-N. Some embodiments may include a number of execution units dedicated to specific functions or sets of functions. Other embodiments may include only one execution unit or one execution unit that can perform a particular function. The illustrated execution logic 450 performs the operations specified by code instructions.

After completion of execution of the operations specified by the code instructions, back end logic 460 retires the instructions of the code 413. In one embodiment, the processor core 400 allows out of order execution but requires in order retirement of instructions. Retirement logic 465 may take a variety of forms as known to those of skill in the art (e.g., re-order buffers or the like). In this manner, the processor core 400 is transformed during execution of the code 413, at least in terms of the output generated by the decoder, the hardware registers and tables utilized by the register renaming logic 425, and any registers (not shown) modified by the execution logic 450.

Although not illustrated in FIG. 12, a processing element may include other elements on chip with the processor core 400. For example, a processing element may include memory control logic along with the processor core 400. The processing element may include I/O control logic and/or may include I/O control logic integrated with memory control logic. The processing element may also include one or more caches.

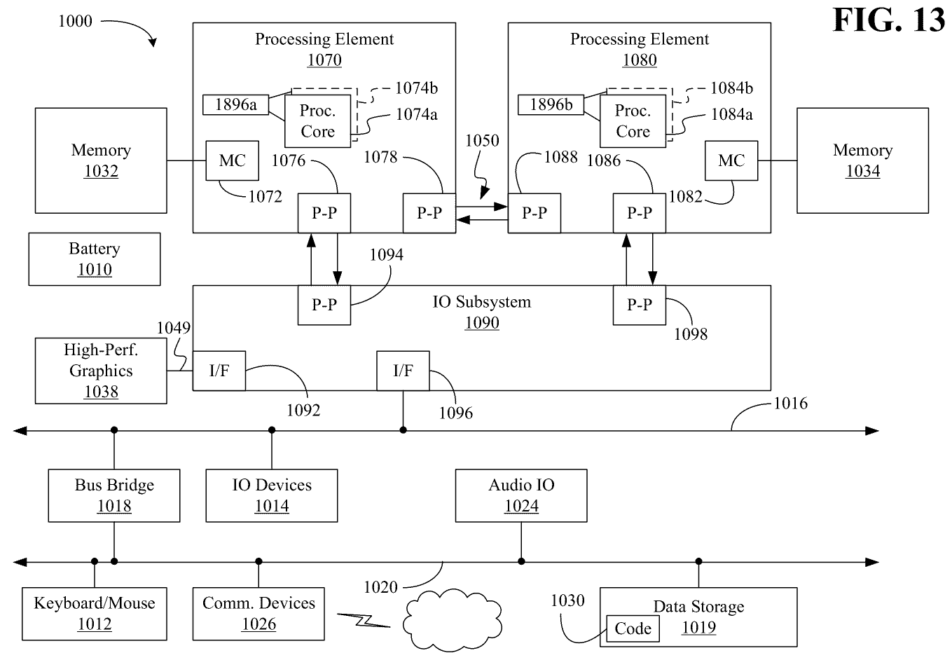

Referring now to FIG. 13, shown is a block diagram of a computing system 1000 embodiment in accordance with an embodiment. Shown in FIG. 13 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood that any or all of the interconnects illustrated in FIG. 13 may be implemented as a multi-drop bus rather than point-to-point interconnect.

As shown in FIG. 13, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner similar to that discussed above in connection with FIG. 12.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments are not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 13, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 13, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments are not so limited.

As shown in FIG. 13, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the placement flow 30, the method 71 (FIG. 5A) and/or the method 70 (FIG. 5B), already discussed. Further, an audio I/O 1024 may be coupled to second bus 1020 and a battery 1010 may supply power to the computing system 1000.

Note that other embodiments are contemplated. For example, instead of the point-to-point architecture of FIG. 13, a system may implement a multi-drop bus or another such communication topology. Also, the elements of FIG. 13 may alternatively be partitioned using more or fewer integrated chips than shown in FIG. 13.

### Additional Notes and Examples

Example 1 includes a performance-enhanced computing system comprising a network controller, a processor coupled to the network controller, and a memory coupled to the processor, wherein the memory includes a set of instructions, which when executed by the processor, cause the processor to receive parameter results and scores of one or more local sessions with respect to subcircuit components in a bounded area, aggregate the parameter results and scores, and generate a global placement model based on the aggregated parameter results and scores.

Example 2 includes the computing system of Example 1, wherein the instructions, when executed, further cause the processor to exclude one or more of design data or layout data from the aggregated parameter results.

Example 3 includes the computing system of Example 1, wherein the one or more local rating sessions include parameterized placements of the subcircuit components in the bounded area, score collections for the parameterized placements, and a training of a local machine learning model based on the parameterized placements and the score collections, and wherein the scores are to be parameterized scores.

Example 4 includes the computing system of Example 1, wherein the plurality of local rating sessions are conducted with respect to a plurality of users.

Example 5 includes the computing system of Example 1, wherein the plurality of local rating sessions are conducted with respect to a plurality of entities.

Example 6 includes the computing system of any one of Examples 1 to 5, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.

Example 7 includes at least one computer readable storage medium comprising a set of instructions, which when executed by a computing system, cause the computing system to receive parameter results and scores of one or more local sessions with respect to subcircuit components in a bounded area, aggregate the parameter results and scores, and generate a global placement model based the aggregated parameter results and scores.

Example 8 includes the at least one computer readable storage medium of Example 7, wherein the instructions, when executed, further cause the computing system to exclude design data from the aggregated parameter results.

Example 9 includes the at least one computer readable storage medium of Example 7, wherein the instructions, when executed, further cause the computing system to exclude layout data from the aggregated parameter results.

Example 10 includes the at least one computer readable storage medium of Example 7, wherein the one or more local rating sessions include parameterized placements of the subcircuit components in the bounded area, score collections for the parameterized placements, and a training of a local machine learning model based on the parameterized placements and the score collections, and wherein the scores are to be parameterized scores.

Example 11 includes the at least one computer readable storage medium of Example 7, wherein the one or more local rating sessions are conducted with respect to a plurality of users.

Example 12 includes the at least one computer readable storage medium of Example 7, wherein the one or more local rating sessions are conducted with respect to a plurality of entities.

Example 13 includes the at least one computer readable storage medium of any one of Examples 7 to 12, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.

Example 14 includes a semiconductor apparatus comprising one or more substrates, and logic coupled to the one or more substrates, wherein the logic is implemented at least partly in one or more of configurable hardware or fixed-functionality hardware, the logic to receive parameter results and scores of one or more local sessions with respect to subcircuit components in a bounded area, aggregate the parameter results and scores, and generate a global placement model based on the aggregated parameter results and scores.

Example 15 includes the semiconductor apparatus of Example 14, wherein the logic is to exclude design data from the aggregated parameter results.

Example 16 includes the semiconductor apparatus of Example 14, wherein the logic is to exclude layout data from the aggregated parameter results.

Example 17 includes the semiconductor apparatus of Example 14, wherein the local rating sessions include parameterized placements of the subcircuit components in the bounded area, score collections for the parameterized placements, and a training of a local machine learning model based on the parameterized placements and the scores, and wherein the score collections are to be parameterized scores.

Example 18 includes the semiconductor apparatus of Example 14, wherein the one or more local rating sessions are conducted with respect to a plurality of users.

Example 19 includes the semiconductor apparatus of Example 14, wherein the one or more local rating sessions are conducted with respect to a plurality of entities.

Example 20 includes the semiconductor apparatus of any one of Examples 14 to 19, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.

Example 21 includes a method of conducting a plurality of local rating sessions with respect to subcircuit components in a bounded area, the method comprising conducting parameterized placements of the subcircuit components in the bounded area, conducting score collections for the parameterized placements, and a conducting a training of a local machine learning model based on the parameterized placements and the score collections.

Example 22 includes a method of operating a performance-enhanced computing system comprising aggregating parameter results and collected scores of a plurality of local rating sessions with respect to subcircuit components in a bounded area, applying a federated machine learning approach to the aggregated parameter results and collected scores, and generating a global placement model based on an output of the federated machine learning approach.

Example 23 includes an apparatus comprising means for performing the methods of any one of Examples 21 to 22.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller;
a processor coupled to the network controller; and
a memory coupled to the processor, wherein the memory includes a set of instructions, which when executed by the processor, cause the processor to:
receive parameter results and scores of one or more local sessions with respect to subcircuit components in a bounded area;
aggregate the parameter results and scores; and
generate a global placement model based on the aggregated parameter results and scores.

2. The computing system of claim 1, wherein the instructions, when executed, further cause the processor to exclude one or more of design data or layout data from the aggregated parameter results.

3. The computing system of claim 1, wherein the one or more local rating sessions include parameterized placements of the subcircuit components in the bounded area, score collections for the parameterized placements, and a training of a local machine learning model based on the parameterized placements and the score collections, and wherein the scores are to be parameterized scores.

4. The computing system of claim 1, wherein the plurality of local rating sessions are conducted with respect to a plurality of users.

5. The computing system of claim 1, wherein the plurality of local rating sessions are conducted with respect to a plurality of entities.

6. The computing system of claim 1, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.

7. At least one computer readable storage medium comprising a set of instructions, which when executed by a computing system, cause the computing system to:
receive parameter results and scores of one or more local sessions with respect to subcircuit components in a bounded area;
aggregate the parameter results and scores; and
generate a global placement model based the aggregated parameter results and scores.

8. The at least one computer readable storage medium of claim 7, wherein the instructions, when executed, further cause the computing system to exclude design data from the aggregated parameter results.

9. The at least one computer readable storage medium of claim 7, wherein the instructions, when executed, further cause the computing system to exclude layout data from the aggregated parameter results.

10. The at least one computer readable storage medium of claim 7, wherein the one or more local rating sessions include parameterized placements of the subcircuit components in the bounded area, score collections for the parameterized placements, and a training of a local machine learning model based on the parameterized placements and the score collections, and wherein the scores are to be parameterized scores.

11. The at least one computer readable storage medium of claim 7, wherein the one or more local rating sessions are conducted with respect to a plurality of users.

12. The at least one computer readable storage medium of claim 7, wherein the one or more local rating sessions are conducted with respect to a plurality of entities.

13. The at least one computer readable storage medium of claim 7, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.

14. A semiconductor apparatus comprising:
one or more substrates; and
logic coupled to the one or more substrates, wherein the logic is implemented at least partly in one or more of configurable hardware or fixed-functionality hardware, the logic to:
receive parameter results and scores of one or more local sessions with respect to subcircuit components in a bounded area;
aggregate the parameter results and scores; and
generate a global placement model based on the aggregated parameter results and scores.

15. The semiconductor apparatus of claim 14, wherein the logic is to exclude design data from the aggregated parameter results.

16. The semiconductor apparatus of claim 14, wherein the logic is to exclude layout data from the aggregated parameter results.

17. The semiconductor apparatus of claim 14, wherein the local rating sessions include parameterized placements of the subcircuit components in the bounded area, score collections for the parameterized placements, and a training of a local machine learning model based on the parameterized placements and the scores, and wherein the score collections are to be parameterized scores.

18. The semiconductor apparatus of claim 14, wherein the one or more local rating sessions are conducted with respect to a plurality of users.

19. The semiconductor apparatus of claim 14, wherein the one or more local rating sessions are conducted with respect to a plurality of entities.

20. The semiconductor apparatus of claim 14, wherein the aggregated parameter results include one or more of a circuit rotation parameter, a recenter procedure parameter, a complexity order parameter, a size parameter, a pin location parameter, a group scheme parameter, a route length weight parameter, a power weight parameter, a convex hull parameter, a local fine tune parameter, an order scheme parameter, a pairing scheme parameter or a second pass parameter.
